(19) United States
(12) Patent Application Publication
(10) Pub. No.: US 2024/0422927 A1
(43) Pub. Date: Dec. 19, 2024

(54) DISPLAY MODULE AND DISPLAY DEVICE

(71) Applicants: Hefei Visionox Technology Co., Ltd., Hefei (CN); KunShan Go-Visionox Opto-Electronics Co., Ltd., Kunshan (CN)

(72) Inventors: Leichao ZHANG, Hefei (CN); Fang ZHANG, Hefei (CN); Yu WANG, Hefei (CN); Xiujian ZHU, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/820,281

(22) Filed: Aug. 30, 2024

Related U.S. Application Data
(63) Continuation of application No. PCT/CN2022/130726, filed on Nov. 8, 2022.

(30) Foreign Application Priority Data
Aug. 31, 2022 (CN) 202211055975.5

(51) Int. Cl. H05K 5/02

(52) U.S. Cl. CPC H05K 5/0217

(57) ABSTRACT

Disclosed are a display module and a display device. The display module includes a flexible screen and a support member stacked sequentially. The support member is located on a backlight side of the flexible screen. The support member includes a fixing portion, a first bending portion and a second bending portion arranged in a first direction, and the first bending portion is located between the fixing portion and the second bending portion. The second bending portion includes a central portion and main bending portions located on two opposite sides of the central portion in the first direction, and stiffness of the central portion is higher than stiffness of the main bending portions. Deformation of the central portion during bending is relatively small, thereby relieving a crease of the central portion, and prolonging an overall service life of the display module and the display device.

### CROSS-REFERENCE TO RELATED APPLICATIONS

This application is a continuation application of International Application No. PCT/CN2022/130726, filed on Nov. 8, 2022, which claims priority to Chinese Patent Application No. 202211055975.5, filed on Aug. 31, 2022. Both of which are hereby incorporated by reference in their entireties.

### TECHNICAL FIELD

The present disclosure relates to the field of display technologies, and in particular, to a display module and a display device.

### BACKGROUND

Flexible display panels have many special product forms such as folding, large-angle bending, and rolling, thereby being increasingly applied.

For example, a larger display area of a foldable display panel may be obtained when the display panel is in an unfolded state. When the display panel is in a folded state, the foldable display panel may have a less storage volume and is convenient to carry, thereby obtaining a wide attention. However, a crease caused by folded state is severe affecting user experience.

However, a problem of crease is relatively severe on the display module mentioned above.

### SUMMARY

In view of at least one technical problem mentioned above, an embodiment of the present disclosure provides a display module and a display device, so as to alleviate crease of the display module, thereby prolonging overall service life of the display module and the display device.

To achieve the foregoing objective, the following technical solutions are provided in embodiments of the present disclosure.

In a first aspect, an embodiment of the present disclosure provides a display module, including a flexible screen and a support member stacked sequentially, and the support member being located on a backlight side of the flexible screen. The support member includes a fixing portion, a first bending portion and a second bending portion arranged in a first direction, the first bending portion is located between the fixing portion and the second bending portion, the second bending portion includes a central portion and main bending portions located on two opposite sides of the central portion in the first direction, and a stiffness of the central portion is higher than a stiffness of the main bending portion.

According to the display module provided by the embodiment of the present disclosure, the display module may include a flexible screen and a support member stacked sequentially with the support member being located on a backlight side of the flexible screen, so that the support member may provide certain support for the flexible screen. The support member may include a fixing portion, a first bending portion and a second bending portion arranged in a first direction, and the first bending portion is located between the fixing portion and the second bending portion. The second bending portion may include a central portion and main bending portions located on two opposite sides of the central portion in the first direction, and a stiffness of the central portion is higher than a stiffness of the main bending portion. As the stiffness of the central portion is relatively large, deformation of the central portion during bending is relatively small, and a bending radius of the central portion is relatively large, thereby relieving a crease of the central portion, and prolonging an overall service life of the display module and the display device. As the stiffness of the main bending portion is relatively small, the main bending portion is more prone to bending, and stress in the second bending portion is mainly distributed on the main bending portions on the two sides of the central portion, rather than on the central portion itself, thereby changing a bending shape of the support member in a bending area and avoiding a severe crease caused by stress concentration in the central portion.

In a possible implementation, a stiffness of the first bending portion is higher than the stiffness of the central portion.

Optionally, the stiffness of the fixing portion is higher than the stiffness of the first bending portion.

Optionally, the stiffness of the central portion increases first and then decreases in the first direction.

Optionally, the stiffness of the main bending portion gradually decreases in a direction from the central portion to the main bending portion; or, the stiffness of the main bending portion decreases first and then increases in the direction from the central portion to the main bending portion.

Optionally, average stiffnesses of two adjacent unit areas of the second bending portion are a first stiffness and a second stiffness, respectively; an absolute value of a difference between the first stiffness and the second stiffness divided by the first stiffness ranges from 0.05 to 0.2.

Optionally, an extension length of the central portion ranges from 1 to 2 mm in the first direction.

Optionally, the support member is an integral structure.

Therefore, the deformation of the first bending portion during bending is relatively small, and a bending radius of the first bending portion is greater, thereby alleviating a crease of the first bending portion.

In a possible implementation, the support member further includes a connecting portion, located between the second bending portion and the first bending portion. A stiffness of the connecting portion is higher than a stiffness of the first bending portion.

Optionally, the stiffness of the connecting portion is equal to a stiffness of the fixing portion.

Therefore, since the stiffness of the fixing portion and the stiffness of the connecting portion are both relatively large, the fixing portion and the connecting portion are not prone to being bent to maintain an unfolded state. When the display module is in the unfolded state, the fixing portion and the connecting portion may provide better support for the flexible screen.

In a possible implementation, a plurality of through holes are provided in the support member at intervals, the through holes penetrate through the support member in a thickness direction of the support member, and a sum of areas of all through holes in a unit area of the central portion is less than a sum of areas of all through holes in the unit area of the main bending portion.

Optionally, a cross section of the through hole is in a strip shape, the through hole extends in a second direction, and the second direction is perpendicular to the first direction.

Optionally, in the second direction, each through hole includes a first end, a second end, and a middle section located between the first end and the second end, and an extension length of the first end, an extension length of the second end, and an extension length of the middle section in the first direction are all greater than an extension length of a remaining part of the through hole in the first direction.

Optionally, a through hole group comprises a plurality of through holes arranged at intervals in the second direction, a quantity of the through hole groups is greater than one and a plurality of the through hole groups are arranged at intervals in the first direction, and through holes of two adjacent through hole groups are arranged in a staggered manner in the second direction.

Therefore, the stiffness of the central portion may be higher than the stiffness of the main bending portion.

In a possible implementation, each through hole has a same area, and a distance between two adjacent through holes of the central portion is greater than a distance between two adjacent through holes of the main bending portion.

Optionally, the distance between two adjacent through holes of the central portion increases first and then decreases in the first direction.

Optionally, the distance between two adjacent through holes of the main bending portion gradually decreases in a direction from the central portion to the main bending portion; or, the distance between two adjacent through holes of the main bending portion decreases first and then increases in the direction from the central portion to the main bending portion.

In a possible implementation, a distance between centers of any two adjacent through holes is the same, and an area of the through hole of the central portion is smaller than an area of the through hole of the main bending portion.

Optionally, the area of the through hole of the central portion decreases first and then increases in the first direction.

Optionally, the area of the through hole of the main bending portion gradually increases in a direction from the central portion to the main bending portion; or, the area of the through hole of the main bending portion increases first and then decreases in the direction from the central portion to the main bending portion.

Therefore, the through holes may be configured in a relatively simple manner.

In a possible implementation, the support member is provided with a groove, an opening of the groove is located on at least one of two opposite surfaces in a thickness direction of the support member.

Therefore, there are various ways to set the groove, thereby applying to a wide range of scenarios.

In a possible implementation, a minimum thickness of the central portion is greater than a minimum thickness of the main bending portion.

Optionally, the minimum thickness of the central portion increases first and then decreases in the first direction;

Optionally, a minimum thickness of the main bending portion gradually decreases in a direction from the central portion to the main bending portion; or, the minimum thickness of the main bending portion decreases first and then increases in the direction from the central portion to the main bending portion.

Therefore, the stiffness of the support member may be adjusted though the minimum thickness.

In a possible implementation, the support member includes a first support layer, a connecting layer and a second support layer sequentially stacked, the second support layer is provided with an opening, the opening penetrates through the second support layer in a thickness direction of the support member, and the opening is located in the main bending portion.

Optionally, the support member further includes a connecting portion located between the second bending portion and the first bending portion, and a groove is formed by encirclement of a second support layer of the connecting portion, a second support layer of the central portion and a connecting layer of the main bending portion.

Therefore, a manufacturing process of the groove may be relatively simple.

In a possible implementation, a thickness of the second support layer is greater than a thickness of the first support layer.

Optionally, a thickness of the second support layer of the central portion is less than a thickness of the second support layer of the fixing portion.

Therefore, support performance and bending performance of the support member may be guaranteed.

In a second aspect, an embodiment of the present disclosure provides a display device, including a first supporting member, a second supporting member, and a display module according to the first aspect mentioned above. The first supporting member and the second supporting member are located on a side, facing away from a flexible screen of the display module, of a support member of the display module, the first supporting member is disposed corresponding to a fixing portion of the support member, and the second supporting member is disposed corresponding to a connecting portion of the support member.

According to the display device provided by the embodiment of the present disclosure, the display device includes a display module, and the display module includes a flexible screen and a support member stacked sequentially with the support member being located on a backlight side of the flexible screen, so that the support member may provide support for the flexible screen. The support member may include a fixing portion, a first bending portion and a second bending portion arranged in a first direction, and the first bending portion is located between the fixing portion and the second bending portion. The second bending portion may include a central portion and main bending portions located on two opposite sides of the central portion in the first direction, and a stiffness of the central portion is higher than a stiffness of the main bending portion. As the stiffness of the central portion is relatively large, deformation of the central portion during bending is relatively small, and a bending radius of the central portion is relatively large, thereby relieving a crease of the central portion, and prolonging an overall service life of the display module and the display device. As the stiffness of the main bending portion is relatively small, the main bending portion is more prone to bending, and stress in the second bending portion is mainly distributed on the main bending portions on the two sides of the central portion, rather than on the central portion itself, thereby changing a bending shape of the support member in a bending area and avoiding a severe crease caused by stress concentration in the central portion.

The construction of the present disclosure, other inventive objects and beneficial effects thereof will become more apparent from the description of preferred embodiments in with reference to the accompanying drawings.

### BRIEF DESCRIPTION OF THE DRAWINGS

In order to provide a clearer explanation of technical solutions of the embodiments provided by the present disclosure or the prior art, accompanying drawings for the embodiments or the prior art description are briefly described below. Obviously the accompanying drawings in the following description are some embodiments of the present disclosure. For those skilled in the art, other accompanying drawings can be obtained based on these drawings without creative efforts.

FIG. 1 is a schematic structural diagram of a support member in a folded state.

FIG. 2a is a schematic structural diagram of a display module in an unfolded state according to an embodiment of the present disclosure.

FIG. 2b is another schematic structural diagram of a display module in an unfolded state according to an embodiment of the present disclosure.

FIG. 3 is a schematic structural diagram of a display module in a folded state according to an embodiment of the present disclosure.

FIG. 4 is a schematic structural diagram of a support member according to an embodiment of the present disclosure.

FIG. 5 is a top view of a support member according to an embodiment of the present disclosure.

FIG. 6 is a schematic structural diagram of a support member provided with through holes according to an embodiment of the present disclosure.

FIG. 7 is a schematic structural diagram of through-hole distribution of a second bending portion according to an embodiment of the present disclosure.

FIG. 8 is another schematic structural diagram of through-hole distribution of a second bending portion according to an embodiment of the present disclosure.

FIG. 9 is a schematic structural diagram of through-hole distribution of a main bending portion according to an embodiment of the present disclosure.

FIG. 10 is another schematic structural diagram of through-hole distribution of a main bending portion according to an embodiment of the present disclosure.

FIG. 11 is another schematic structural diagram of through-hole distribution of a second bending portion according to an embodiment of the present disclosure.

FIG. 12 is a schematic structural diagram of an opening of a groove located on a first surface according to an embodiment of the present disclosure.

FIG. 13 is a schematic structural diagram of an opening of a groove located on a second surface according to an embodiment of the present disclosure.

FIG. 14 is a schematic structural diagram of an opening of a groove located on a first surface and a second surface separately according to an embodiment of the present disclosure.

FIG. 15 is a schematic structural diagram of a support member of a multi-layer stacked structure according to an embodiment of the present disclosure.

FIG. 16 is a curves graph of crease depths of a display module provided by Example 1 and Example 2.

FIG. 17 is a schematic structural diagram of a display device according to an embodiment of the present disclosure.

FIG. 18 is a schematic structural diagram of a display device in an unfolded state according to an embodiment of the present disclosure.

FIG. 19 is a schematic structural diagram of a display device in a folded state according to an embodiment of the present disclosure.

### DETAILED DESCRIPTION OF THE EMBODIMENTS

In related technologies, a display module may include a flexible screen and a support member with the support member being located on a backlight side of the flexible screen, so that the support member may provide certain support for the flexible screen. In addition, the support member may drive the flexible screen to be bent or flattened under an external force.

However, during a bending process of the display module, various film layers located in a bending area of the display module are deformed under an external force, and deformation recovery capability of materials of the film layers is limited. When a deformation exceeds an elastic limit of the material, the deformation of the material may turn into an irreversible plastic deformation; after the external force is removed, the deformation may not be completely eliminated, and the material may not be completely restored to an original shape. Therefore, a crease may be formed in the bending area of the display module, thereby affecting an overall service life of the display module and the display device.

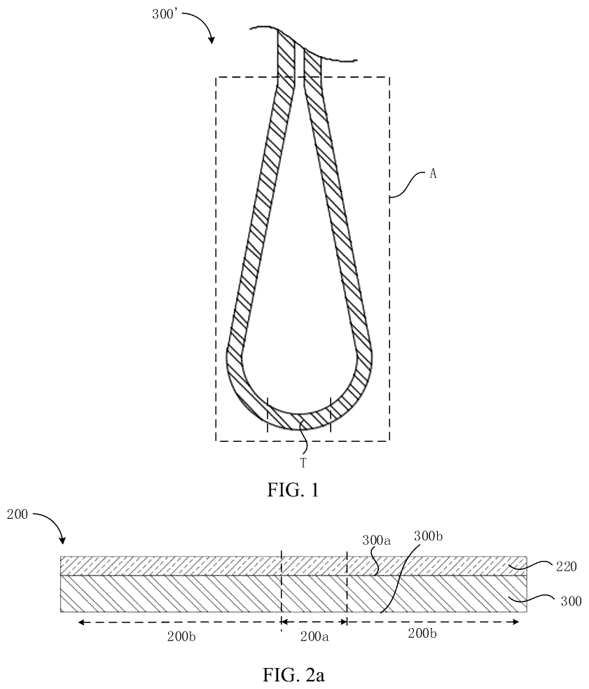

As shown in FIG. 1, taking a support member 300′ as an example, the support member 300′ located in a bending area forms a bending portion A. The bending portion A includes a central bending portion T close to a central position of the bending portion A. The closer to the central bending portion T, the less a bending radius of the support member 300′. A bending radius of the central bending portion T is less than a bending radius of the remaining part of the bending portion A, so that a crease of the central bending portion T is relatively severe. Thus, a crease of the display module is caused to be relatively severe (for example, a crease of the central bending portion T may present in a “V” shape).

Based on at least one technical problem mentioned above, the present embodiment provides a display module and a display device. The display module includes a flexible screen and a support member stacked sequentially with the support member being located on a backlight side of the flexible screen, so that the support member may provide certain support for the flexible screen. The support member may include a fixing portion, a first bending portion and a second bending portion arranged in a first direction, and the first bending portion is located between the fixing portion and the second bending portion. The second bending portion may include a central portion and main bending portions located on two opposite sides of the central portion in the first direction, and a stiffness of the central portion is higher than a stiffness of the main bending portion. As the stiffness of the central portion is relatively large, deformation of the central portion during bending is relatively small, and a bending radius of the central portion is relatively large, thereby relieving a crease of the central portion, and prolonging an overall service life of the display module and the display device. As the stiffness of the main bending portion is relatively small, the main bending portion is more prone to bending, and stress in the second bending portion is mainly distributed on the main bending portions on the two sides of the central portion, rather than on the central portion itself, thereby changing a bending shape of the support member in a bending area and avoiding a severe crease caused by stress concentration in the central portion.

In order to make purposes, technical solution, and advantages of the embodiments of the present disclosure clearer, a clear and complete description of the technical solution in the embodiments of the present disclosure will be provided with reference to the accompanying drawings in the following. Obviously, the described embodiments are a part of the embodiments of the present disclosure, not all of them. Based on the embodiments in the present disclosure, all other embodiments obtained by those skilled in the art without creative efforts fall within the protection scope of the present disclosure.

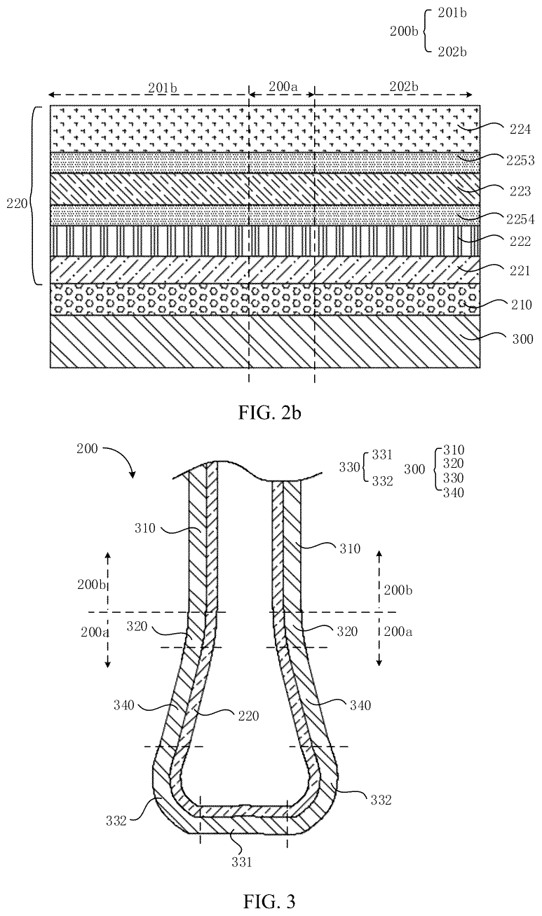

A display module 200 provided in the embodiments of the present disclosure will be described below with reference to FIGS. 2a to 19.

As shown in FIG. 2a, the display module 200 may include a flexible screen 220. The flexible screen 220 may be an organic light-emitting diode (OLED) display screen, or a micro-light emitting diode (Micro LED or μLED) display screen.

The flexible screen 220 may include a light-emitting side and a backlight side opposite to each other. The light-emitting side may be configured to display an image, and the backlight side is another side, disposed opposite to the light-emitting side, of the flexible screen 220. An upper side of the flexible screen 220 shown in FIG. 2a is the light-emitting side, and a lower side of the flexible screen 220 shown in FIG. 2a is the backlight side.

The display module 200 may include a support member 300 located on the backlight side of the flexible screen 220. The support member 300 is configured to provide certain support for the flexible screen 220. When the flexible screen 220 is in an unfolded state, the support member 300 may improve flatness of the flexible screen 220, thereby effectively improving display effect of the flexible screen 220. When the flexible screen 220 is in a folded state, the support member 300 may control a folding form of the flexible screen 220 through a structural design of the support member 300, thereby improving experience of users.

As shown in FIG. 5, the display module 200 may include a first direction X, and the first direction X may be a width direction of the display module 200. The display module 200 may include a second direction Y, and the second direction Y may be a length direction of the display module 200. The display module 200 may include a third direction, and the third direction may be a thickness direction of the display module 200. The length, the width, the thickness, and the like in the embodiments of the present disclosure are merely for ease of description, and do not mean any limitation on a size. For example, the width may be greater than, equal to, or less than the length. In this case, the first direction X may be understood as a straight direction when the product is unfolded, and a direction corresponding to a bending direction when the product is folded.

As shown in FIG. 2a, the display module 200 may include a bending area 200a and a non-bending area 200b, and the bending area 200a and the non-bending area 200b are arranged adjacent to each other. For example, the bending area 200a and the non-bending area 200b may be disposed adjacent to each other in the first direction X (FIG. 5), and the first direction X is a layout direction of the bending area 200a and the non-bending area 200b. A quantity of the bending area 200a and a quantity of the non-bending area 200b are both at least one, and one bending area 200a and one non-bending area 200b are alternately arranged. For example, the quantity of the bending area 200a may be one, two, three, or more than three. The quantity of the non-bending area 200b may be one, two, three, or more than three.

Description of the embodiment of the present disclosure will be provided by taking the quantity of the bending area 200a as one, the quantity of the non-bending areas 200b as two, and the two non-bending areas 200b connected by the bending area 200a as an example.

As shown in FIG. 2b, the two non-bending areas 200b may include a first non-bending area 201b and a second non-bending area 202b. The bending area 200a is located between the first non-bending area 201b and the second non-bending area 202b. The display module 200 located in the bending area 200a may be bent and flattened, so that folding and unfolding of the display module 200 is achieved.

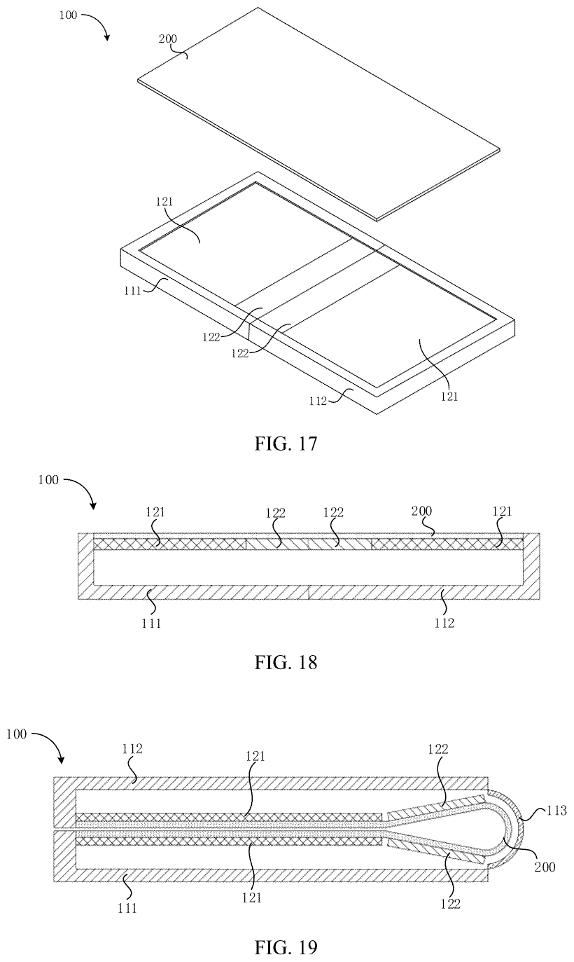

It should be noted that the display module 200 may include an unfolded state, a folded state, and an intermediate state between them. The state in which the display module 200 is located is also a state in which the flexible screen 220, the support member 300, and the display device 100 (FIG. 17) are located. After the support member 300 is bonded with the flexible screen 220, a user may apply a force to the flexible screen 220 through the support member 300, and the support member 300 may drive the flexible screen 220 to switch between the unfolded state and the folded state.

As shown in FIG. 2b, the unfolded state refers to a state in which each part of the display module 200 is roughly in a same plane. At this point, the first non-bending area 201b, the second non-bending area 202b, and the bending area 200a are roughly on the same plane, and an included angle between the first non-bending area 201b and the second non-bending area 202b is approximately 180 degrees. In the unfolded state, a display area of the display module 200 is relatively large to ensure better user experience.

As shown in FIG. 2b and FIG. 3, the folded state refers to that the bending area 200a of the display module 200 is bent, and the display module 200 of the first non-bending area 201b at least partially overlap with the display module 200 of the second non-bending area 202b in the thickness direction of the display module 200. The included angle between the first non-bending area 201b and the second non-bending area 202b is approximately 0 degree. In the folded state, the display module 200 and the display device 100 including the display module 200 are small in size, so that storage and carrying of the display device 100 is facilitated.

In some embodiments, the display device 100 may be an inward foldable display device, that is, when the display device 100 is in the folded state, the folded flexible screen 220 is located on an inner side of the support member 300, and the support member 300 may protect the flexible screen 220. At this time, the flexible screen 220 of the first non-bending area 201b and the flexible screen 220 of the second non-bending area 202b are disposed facing each other.

In some embodiments, the display device 100 may be an outward foldable display device, that is, when the display device 100 is in the folded state, the folded flexible screen 220 is located outside the support member 300, and the flexible screen 220 may achieve a display function in the folded state to meet requirements in different display scenes. At this time, the flexible screen 220 of the first non-bending area 201b and the flexible screen 220 of the second non-bending area 202 b are disposed back to back.

A description of the flexible screen 220 provided by the embodiments of the present disclosure is provided below.

As shown in FIG. 2b, a protective layer 210 may be provided between the support member 300 and the flexible screen 220, and the protective layer 210 is configured to protect the flexible screen 220. A first connecting layer (not shown) may be provided between the protective layer 210 and the support member 300, and a second connecting layer may be provided between the protective layer 210 and the flexible screen 220, so that the protective layer 210 is stably bonded to the support member 300 and the flexible screen 220, respectively. For example, the connecting layer (the first connecting layer and/or the second connecting layer) may be obtained from optically clear adhesive, optically transparent resin, pressure-sensitive adhesive, and the like.

The flexible screen 220 may include a substrate and a light-emitting layer 222 located on the substrate. The substrate may provide support for the remaining structural layers to be disposed subsequently. The substrate may be a flexible substrate. A buffer layer 221 is provided between the substrate and the light-emitting layer 222, as the buffer layer 221 may block water and oxygen from penetrating through the substrate and entering structure layers on the buffer layer 221 to prevent corrosion.

The light-emitting layer 222 may include an anode layer, a pixel layer, and a cathode layer stacked sequentially, and the anode layer is located on a side, facing the substrate, of the cathode layer. The anode layer may be a pixel electrode, and the cathode layer may be a common electrode.

The flexible screen 220 may include a light filter layer 223 located on a side, facing away from the substrate, of the light-emitting layer 222. The light filter layer 223 is configured to reduce reflection of an ambient light, thereby improving display effect of the flexible screen 220. For example, the light filter layer 223 may be a polarizer.

The flexible screen 220 may include a cover plate 224, located on a side, facing away from the substrate, of the light filter layer 223, and the cover plate 224 is configured to protect the flexible screen 220, so as to avoid scratching on the flexible screen 220 when the flexible screen 220 is used by a user. For example, a third connecting layer 2253 may be provided between the cover plate 224 and the light filter layer 223, and the third connecting layer 2253 is configured to bond the cover plate 224 with the light filter layer 223. In addition, the third connecting layer 2253 may be further configured to provide a flat surface. A fourth connecting layer 2254 may further be provided between the light filter layer 223 and the light-emitting layer 222.

A description of the support member 300 provided by the embodiments of the present disclosure will be given below.

As shown in FIG. 2a, the support member 300 may include a first surface 300a and a second surface 300b disposed opposite to each other in the thickness direction. The first surface 300a is a surface, close to the flexible screen 220, of the support member 300, and the second surface 300b is a surface, facing away from the flexible screen 220, of the support member 300. For example, a material of the support member 300 may include a metal material such as stainless steel, titanium alloy, and magnesium aluminum alloy. Alternatively, the material of the support member 300 may further include a non-metallic material such as glass or plastic.

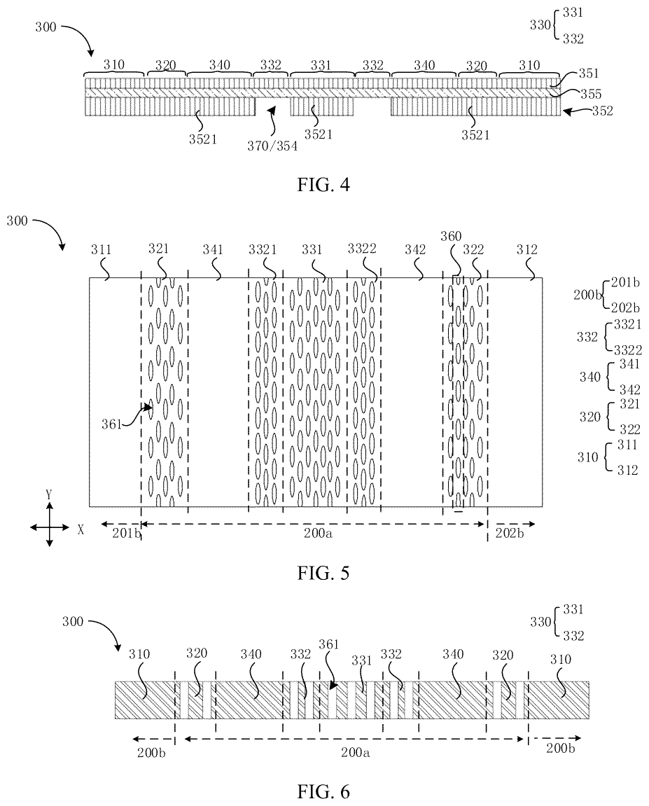

In some examples, the support member 300 may be an integrated structure. All parts of the support member 300 are of an integral structure, so that overall structural stability of the support member 300 is relatively high. In some other examples, as shown in FIG. 4, the support member 300 may be a multi-layer stacked structure. The support member 300 may include a first support layer 351 and a second support layer 352 that are stacked, and the first support layer 351 and the second support layer 352 are connected through a fifth connecting layer 355. That is, the support member 300 may include the first support layer 351, the fifth connecting layer 355, and the second support layer 352 sequentially stacked. The first support layer 351 may be located on a side, facing the flexible screen 220, of the second support layer 352, or the first support layer 351 may be located on a side, facing away from the flexible screen 220, of the second support layer 352. It is taken as an example that the first support layer 351 is located on the side, facing the flexible screen 220, of the second support layer 352 to describe the embodiment of the present disclosure.

Materials, thicknesses, and other parameters of any two connecting layers of the display module 200, namely the first connecting layer, the second connecting layer, the third connecting layer 2253, the fourth connecting layer 2254, and the fifth connecting layer 355, may be the same or different.

As shown in FIG. 3 and FIG. 5, the support member 300 may include a fixing portion 310 located in the non-bending area 200b (only a part of the non-bending area 200b is shown in FIG. 5), a fixing portion 310 in the first non-bending area 201b may be a first fixing portion 311, and a fixing portion 310 in the second non-bending area 202b may be a second fixing portion 312. The support member 300 may further include a second bending portion 330 located in the bending area 200a. The fixing portion 310 and the second bending portion 330 are arranged in the first direction X. The second bending portion 330 may include a central portion 331 and main bending portions 332 located on two opposite sides of the central portion 331 in the first direction X. The central portion 331 is provided between the two main bending portions 332, and the main bending portion 332 is located between the fixing portion 310 and the central portion 331. A main bending portion 332 between the first fixing portion 311 and the central portion 331 is a first main bending portion 3321, and a main bending portion 332 between the second fixing portion 312 and the central portion 331 is a second main bending portion 3322.

Exemplarily, in the first direction X, an extension length of the central portion 331 may range from 1 mm to 2 mm, so that it may be avoided that the extension length of the central portion 331 is too small, thereby avoiding the bending radius of the central portion 331 being too small. Meanwhile, it may be avoided that the extension length of the central portion 331 is too large, thereby avoiding greatly effect on a size of the display device 100 caused by the central portion 331. For example, the extension length of the central portion 331 may be 1 mm, 1.2 mm, 1.4 mm, 1.6 mm, 1.8 mm, 2 mm, or any value between 1 mm and 2 mm.

As shown in FIG. 3, the support member 300 may further include a first bending portion 320 located between the second bending portion 330 and the fixing portion 310. The second bending portion 330 is provided with the first bending portions 320 on two opposite sides in the first direction X (FIG. 5). In addition, the support member 300 may further include a connecting portion 340 located between the second bending portion 330 and the first bending portion 320. As shown in FIG. 5, a first bending portion 320 and a connecting portion 340 located between the first fixing portion 311 and the second bending portion 330 are respectively a first sub-bending portion 321 and a first connecting portion 341; a first bending portion 320 and a connecting portion 340 located between the second fixing portion 312 and the second bending portion 330 are respectively a second sub-bending portion 322 and a second connecting portion 342. That is, the support member 300 is sequentially provided with the first fixing portion 311, the first sub-bending portion 321, the first connecting portion 341, the first main bending portion 3321, the central portion 331, the second main bending portion 3322, the second connecting portion 342, the second sub-bending portion 322, and the second fixing portion 312 in the first direction X.

For example, the display module 200 may be bent in a water drop shape, so that a distance between flexible screens 220 of the two non-bending areas 200b is relatively close, and external dust may be reduced from entering between the two flexible screens 220, thereby protecting the flexible screens 220. When the display device 100 is an inward foldable display device, the second bending portion 330 is bent inward and subjected to compressive stress; and the first bending portion 320 is bent outward and subjected to tensile stress. When the display device 100 is an outward foldable display device, the second bending portion 330 is bent outward and subjected to tensile stress; and the first bending portion 320 is bent inward and subjected to compressive stress.

A description of stiffness of the support member 300 provided by the embodiments of the present disclosure will be given below.

In some embodiments, a stiffness of the central portion 331 may be higher than a stiffness of the main bending portion 332. As the central portion 331 has a higher stiffness, deformation of the central portion 331 during bending may be relatively small and a bending radius of the central portion 331 is greater, so that the central portion 331 is more flat during bending, thereby alleviating a crease in the central portion 331. Thus, the crease of the central portion 331 is more flat, so that the crease of the display module 200 may be alleviated, thereby prolonging an overall service life of the display module 200 and the display device 100. As the stiffness of the main bending portion 332 relatively small, the main bending portion 332 is more prone to bending and a bending radius of the main bending portion 332 is less than the bending radius of the central portion 331. Thus, stress in the second bending portion 330 is mainly distributed on the main bending portions 332 on the two sides of the central portion 331, rather than on the central portion 331 itself, so that a bending shape of the support member 300 in the bending area 200a may be changed, and a severe crease caused by a stress concentration in the central portion 331 is avoided, so as to alleviate the crease of the display module 200.

In some embodiments, the stiffness of the central portion 331 may be less than a stiffness of the first bending portion 320. As the stiffness of the first bending portion 320 is higher than the stiffness of the central portion 331, deformation of the first bending portion 320 during bending is relatively small and a bending radius of the first bending portion 320 is greater, so that a crease of the first bending portion 320 may be alleviated. Thus, the crease of the first bending portion 320 is more flat, thereby alleviating the crease of the display module 200 and prolonging an overall service life of the display module 200 and the display device 100.

In some embodiments, a stiffness of the fixing portion 310 may be higher than the stiffness of the first bending portion 320. In addition, a stiffness of the connecting portion 340 may be higher than the stiffness of the first bending portion 320. When the display module 200 is in a folded state, due to higher stiffnesses of the fixing portion 310 and the connecting portion 340, the fixing portion 310 and the connecting portion 340 are not easily bent and remain in a flat state. When the display module 200 is in an unfolded state, the fixing portion 310 and the connecting portion 340 may have a better support effect on the flexible screen 220. For example, the stiffness of the connecting portion 340 may be equal to the stiffness of the fixing portion 310, thereby simplifying preparation difficulty of the fixing portion 310 and the connecting portion 340.

Stiffness refers to an ability of a structure to resist elastic deformation when the structure is subjected to force, and is a characterization for a degree of difficulty in structural elastic deformation. The higher the stiffness is, the higher the stress is required to cause a deformation. The less the stiffness is, the lower the stress is required to cause the deformation, and the better bending performance is.

In the following, a changing trend of the stiffness of the second bending portion 330 provided by the embodiment of the present embodiment will be described in detail.

In some embodiments, in the first direction X, a stiffness of the central portion 331 may increase first and then decrease, that is, the stiffness of the central portion 331 may gradually decrease from the middle to both sides. Thus, the stiffness of the central portion 331 is distributed in a pattern of large in the middle and small on both sides. The stiffness of the central portion 331 in the first direction X is less on both sides, and is closer to a stiffness of the main bending portion 332, so that local stress concentration caused by stiffness mutation between the central portion 331 and the main bending portion 332 may be avoided. In addition, local stress concentration caused by stiffness mutation in the central portion 331 may be further avoided, so that a creases of the support member 300 may be alleviated, and the support member 300 is prevented from being broken due to the stress concentration.

In some embodiments, a stiffness of the main bending portion 332 may gradually decrease in a direction from the central portion 331 to the main bending portion 332. Thus, a stiffness of a side, close to the central portion 331, of the main bending portion 332 is greater, and is closer to the stiffness of the central portion 331, so that local stress concentration caused by stiffness mutation between the central portion 331 and the main bending portion 332 may be avoided. In addition, local stress concentration caused by stiffness mutation in the main bending portion 332 may be avoided, so that a crease of the support member 300 may be alleviated, and the support member 300 is prevented from being broken due to stress concentration.

In some embodiments, in a direction from the central portion 331 to the main bending portion 332, the stiffness of the main bending portion 332 may decrease first and then increase, that is, the stiffness of the main bending portion 332 may gradually increase from the middle to the two sides. Thus, the stiffness of the main bending portion 332 is distributed in a pattern of small in the middle and large on both sides, and the stiffness of the main bending portions 332 on two opposite sides in the first direction X is greater. A stiffness of a side, close to the central portion 331, of the main bending portion 332 is closer to the stiffness of the central portion 331, so that local stress concentration caused by stiffness mutation between the central portion 331 and the main bending portion 332 may be avoided. A stiffness of a side, close to the connecting portion 340, of the main bending portion 332 is closer to a stiffness of the connecting portion 340, so that local stress concentration caused by stiffness mutation between the connecting portion 340 and the main bending portion 332 may be avoided. In addition, local stress concentration caused by stiffness mutation in the main bending portion 332 may further be avoided, so that a crease of the support member 300 may be alleviated, and the support member 300 is prevented from being broken due to the stress concentration.

Exemplarily, average stiffnesses of two adjacent unit areas of the second bending portion 330 may be a first stiffness and a second stiffness, respectively, and an absolute value of a difference between the first stiffness and the second stiffness divided by the first stiffness ranges from 0.05 to 0.2. It may be avoided that a difference between the stiffnesses of the second bending portion 330 in two adjacent unit areas is too small, so that a stiffness difference between the central portion 331 and the main bending portion 332 may be prevented from being too small to alleviate a crease. The stiffness difference of the second bending portion 330 in two adjacent unit areas may further be prevented from being too large, so that the second bending portion 330 in two adjacent unit areas may be prevented from generating stress concentration due to stiffness mutation. For example, a magnitude of the absolute value divided by the first stiffness may be 0.05, 0.1, 0.15, 0.2, or any value between 0.05 and 0.2.

The stiffness of the support member 300 may be adjusted by providing a notch on the support member 300. Compared with a support member 300 that is not provided with the notch, a part of the support member 300 needs to be removed to form the notch for the support member 300 provided with the notch, so that the stiffness of the support member 300 may be reduced by the notch. The notch may be formed through a through hole 361 (FIG. 6) and/or a groove 370 (FIG. 4). For example, a shape of an orthographic projection of an inner wall of the notch on the flexible screen 220 may include, but is not limited to, a circle, an ellipse, a strip, a polygon (for example, a diamond, a ladder), and the like.

In the following, a support member 300 provided with a through hole 361 according to the embodiment of the present disclosure will be described.

As shown in FIG. 6, the support member 300 may be provided with a plurality of through holes 361 arranged at intervals, and the through holes 361 penetrate through the support member 300 in a thickness direction of the support member 300. The stiffness of the support member 300 may be adjusted by adjusting a quantity of the through holes 361, a cross-sectional area of a single through hole 361, a spacing between two adjacent through holes 361, and the like. The higher a sum of areas of all through holes 361 of the support member 300 in a unit area is, the less a stiffness of the support member 300 in the unit area is. A sum of areas (cross-sectional areas) of all through holes 361 of the central portion 331 in a unit area may be configured to be less than a sum of areas of all through holes 361 of the main bending portion 332 in the unit area. In this way, the stiffness of the central portion 331 may be higher than the stiffness of the main bending portion 332, so that a crease of the display module 200 may be alleviated, of which the principle has been explained and will is not be repeated.

As shown in FIG. 5, a plurality of through holes 361 are arranged at intervals in the first direction X and constitute a plurality of through hole groups 360 (that is, the plurality of through holes 361 in a same column constitute the through hole group 360 as shown in FIG. 5). Each through hole group 360 includes a plurality of through holes 361 arranged at intervals in the second direction Y. The through holes 361 of two adjacent through hole groups 360 are arranged in a staggered manner in the second direction Y. There is a gap between two adjacent through holes 361 in each through hole group 360. In two adjacent through hole groups 360, at least a part of the through hole 361 in one of the through hole groups 360 is disposed corresponding to gaps in the other through hole group 360, so that the gaps in the two adjacent through hole groups 360 may be arranged in a staggered manner. Since the gap is a part that is not provided with the through holes 361, a stiffness of the gap is relatively large. When the gaps are staggered, it may be avoided that bending performance of the support member 300 provided with the plurality of through holes groups 360 is affected by concentration of the gaps. In addition, stress concentration may be avoided in the support member 300, so that fatigue damage caused by multiple times of bending may be reduced, thereby prolonging the service life of the product.

As shown in FIG. 7, a cross section of the through hole 361 is in a strip shape, that is, an orthographic projection of an inner wall of the through hole 361 on the flexible screen 220 is in a strip shape. The cross section of the through hole 361 refers to a cross section, parallel to a plane where the support member 300 is located, of the through hole 361. The through hole 361 may extend in the second direction Y, that is, a length direction of the through hole 361 is consistent with the second direction Y. Thus, bending performance of the support member 300 provided with the through holes 361 may be improved.

In the second direction Y, the through hole 361 may include a first end 3611 and a second end 3612, and the first end 3611 and the second end 3612 may be two opposite ends of the through hole 361 in the second direction Y. A part of the through hole 361 located between the first end 3611 and the second end 3612 is a middle section 3613. An extension length of the first end 3611, the second end 3612 and the middle section 3613 in the first direction X may be all greater than an extension length of the other remaining part of the through hole 361 in the first direction X. In the second direction Y, there is a gap between two adjacent through holes 361. The first end 3611 and the second end 3612 are disposed adjacent to the gap. As the extension length of the first end 3611 and the second end 3612 in the first direction X is configured to be relatively large, a stiffness of the support member 300 at the gap may be reduced, so that it may be avoided that the bending performance of the support member 300 is affected by an excessive stiffness of the support member 300 at the gap.

In two adjacent through hole groups 360, a middle section 3613 of one of the through hole groups 360 may be disposed corresponding to a gap between two adjacent through holes 361 of the other through hole group 360, so that the middle section 3613 of one of the through hole groups 360 is adjacent to the gap of the other through hole group 360. The middle section 3613 may reduce the stiffness of the support member 300 at the gap, so that it may be avoided that the bending performance of the support member 300 is affected by an excessive stiffness of the support member 300 at the gap.

It can be understood that, within a unit area of support member 300, a sum of cross-sectional areas of all through holes 361 is equal to the quantity of the through holes 361 multiplied by a cross-sectional area of a single through hole 361 (which may be referred to as an area for short).

In a first implementation, a cross-sectional area of a single through hole 361 may be equal to each other. The fewer the quantity of the through holes 361 is, the less the sum of the cross-sectional areas of all through holes 361 is, and the higher the stiffness of the support member 300. When the cross-sectional area of each through hole 361 is the same, a distance between adjacent through holes 361 of the central portion 331 (W in FIG. 7) may be greater than a distance between adjacent through holes 361 of the main bending portion 332. Thus, a quantity of through holes 361 of the central portion 331 in a unit area is less than a quantity of through holes 361 of the main bending portion 332 in the unit area, that is, a sum of the cross-sectional areas of all through holes 361 of the central portion 331 in a unit area is less than a sum of the cross-sectional areas of all through holes 361 of the main bending portion 332 in the unit area. Thus, the stiffness of the central portion 331 may be higher than the stiffness of the main bending portion 332, thereby alleviating the crease of the display module 200, of which the principle has been explained and will not be repeated.

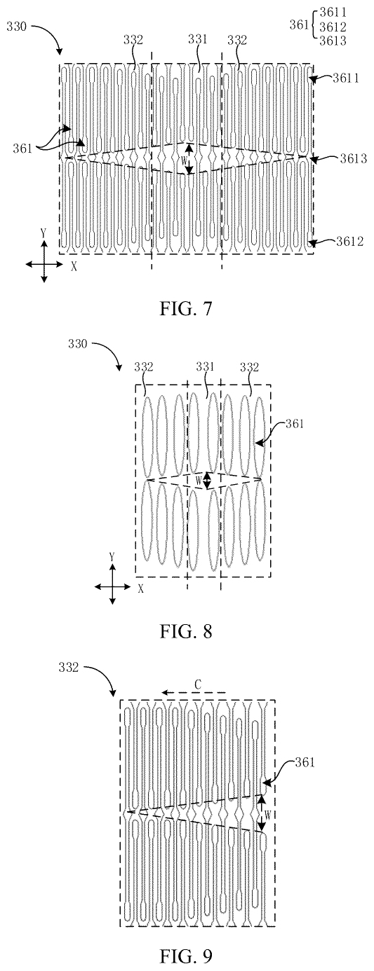

Exemplarily, as shown in FIG. 7 and FIG. 8, in the first direction X, a distance W between two adjacent through holes 361 of the central portion 331 may increase first and then decrease. Thus, in the first direction X, the stiffness of the central portion 331 may gradually decrease from the middle to both sides, so that local stress concentration caused by stiffness mutation between the central portion 331 and the main bending portion 332, as well as in the central portion 331 may be avoided, thereby alleviating the crease of the support member 300 and avoiding support member 300 from being broken, of which the principle has been explained and will not be repeated.

Exemplarily, as shown in FIG. 9, in a direction from the central portion 331 to the main bending portion 332 (direction C in FIG. 9), a distance W between two adjacent through holes 361 of the main bending portion 332 may gradually decrease. Thus, the stiffness of the main bending portion 332 gradually decreases in the direction from the central portion 331 to the main bending portion 332 so that the local stress concentration caused by stiffness mutation between the central portion 331 and the main bending portion 332, as well as in the main bending portion 332 may be avoided, thereby alleviating the crease of the support member 300 and avoiding support member 300 from being broken, of which the principle has been explained and will not be repeated.

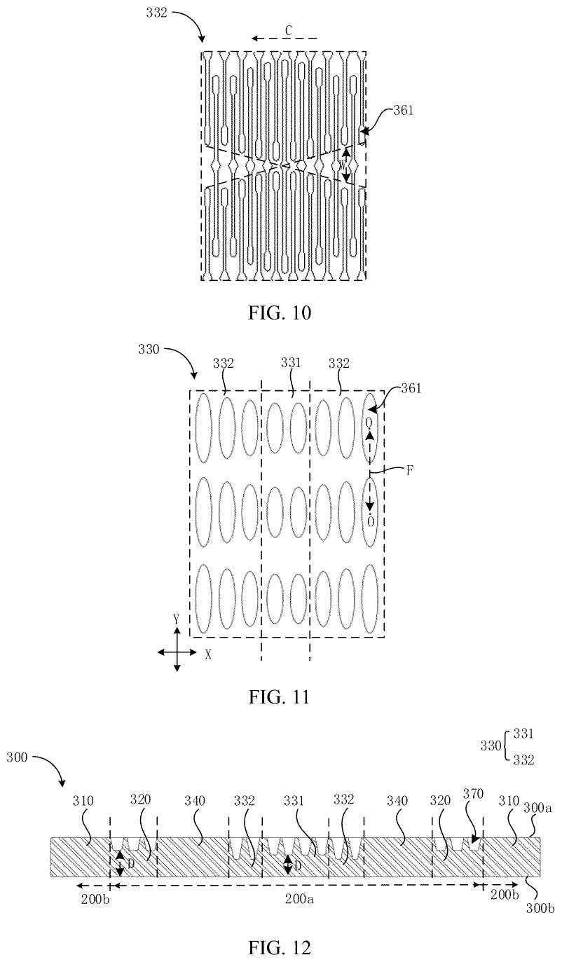

Exemplarily, as shown in FIG. 10, in a direction from the central portion 331 to the main bending portion 332 (direction C in FIG. 10), a distance W between adjacent through holes 361 of the main bending portion 332 may decrease first and then increase. Thus, in the first direction X, the stiffness of the main bending portion 332 may gradually increase from the middle to both sides, so that local stress concentration caused by stiffness mutation between the central portion 331 and the main bending portion 332, between the connecting portion 340 and the main bending portion 332, as well as in the main bending portion 332 is avoided, thereby alleviating the creases of the support member 300 and avoiding support member 300 from being broken, of which the principle has been explained and will not be repeated.

In a second implementation, as shown in FIG. 11, a distance F between centers O of any two adjacent through holes 361 may be equal to each other, so that a quantity of the through holes 361 provided in the support member 300 per unit area may be the same, leading to a regular arrangement of a plurality of through holes 361. A cross-sectional area of a single through hole 361 of the central portion 331 is less than a cross-sectional area of a single through hole 361 of the main bending portion 332, so that a sum of cross-sectional areas of all through holes 361 of the central portion 331 in a unit area is less than a sum of cross-sectional areas of all through holes 361 of the main bending portion 332 in the unit area. Thus, the stiffness of the central portion 331 may be higher than the stiffness of the main bending portion 332, thereby alleviating the creases of the display module 200, of which the principle has been explained and will not be repeated.

Exemplarily, a cross-sectional area of the through hole 361 of the central portion 331 decreases first and then increases in the first direction X. Thus, the stiffness of the central portion 331 may gradually decrease from the middle to both sides in the first direction X, thereby alleviating the creases of the support member 300 and avoiding support member 300 from being broken, of which the principle has been explained and will not be repeated.

Exemplarily, a cross-sectional area of the through hole 361 of the main bending portion 332 gradually increases in a direction from the central portion 331 to the main bending portion 332. Thus, the stiffness of the main bending portion 332 gradually decreases in the direction from the central portion 331 to the main bending portion 332, thereby alleviating the creases of the support member 300 and avoiding support member 300 from being broken, of which the principle has been explained and will not be repeated.

Exemplarily, a cross-sectional area of the through-hole 361 of the main bending portion 332 increases first and then decreases in a direction from the central portion 331 to the main bending portion 332. Thus, in the first direction X, the stiffness of the main bending portion 332 may gradually increase from the middle to both sides, thereby alleviating the creases of the support member 300 and avoiding support member 300 from being broken, of which the principle has been explained and will not be repeated.

A description of a support member 300 provided with a groove 370 in an embodiment of the present disclosure will be given in the following.

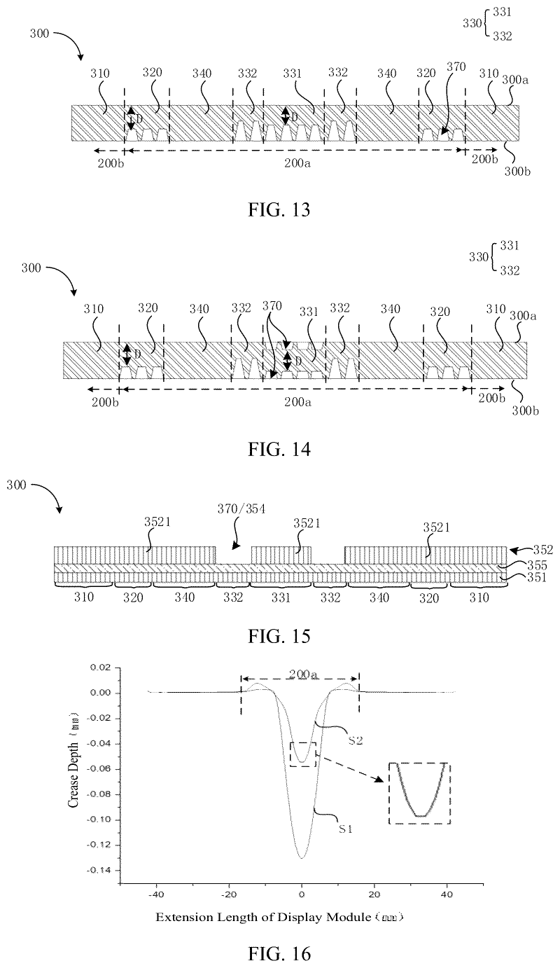

As shown in FIGS. 12 to 14, a groove 370 may be provided on the support member 300, and an opening of the groove 370 is located on at least one of two opposite surfaces in a thickness direction of the support member 300. The stiffness of the support member 300 may be adjusted by adjusting a groove depth of groove 370, a cross-sectional area of a single groove 370, a quantity of the groove 370, and a distance between adjacent grooves 370. For example, as shown in FIG. 12, an opening of groove 370 may be located on a first surface 300a; alternatively, as shown in FIG. 13, an opening of groove 370 may be located on a second surface 300b to prevent the groove 370 from affecting a flatness of the flexible screen 220. Alternatively, as shown in FIG. 14, an opening of groove 370 may be located both on the first surface 300a and the second surface 300b.

When minimum thicknesses D (FIG. 12) at different positions of the support member 300 are different, the higher the minimum thickness D is, the higher the stiffness of the support member 300 is. The less the minimum thickness D is, the less the stiffness of the support member 300 is. In some embodiments, as shown in FIG. 14, a minimum thickness D of the central portion 331 may be higher than a minimum thickness D of the main bending portion 332, so that the stiffness of the central portion 331 is higher than the stiffness of the main bending portion 332, thereby alleviating the creases of the support member 300, of which the principle has been explained and will not be repeated.

Taking a central portion 331 provided with a groove 370 as an example, in an implementation where an opening of the groove 370 is located on the first surface 300a, as shown in FIG. 12, a minimum thickness D of the central portion 331 may be a minimum distance between a bottom wall of the groove 370 and the second surface 300b. In an implementation where an opening of the groove 370 is located on the second surface 300b, as shown in FIG. 13, a minimum thickness D of the central portion 331 may be a minimum distance between a bottom wall of the groove 370 and the first surface 300a. In an implementation where grooves 370 are provided on both the first surface 300a and the second surface 300b, as shown in FIG. 14, an orthogonal projection of the groove 370 with an opening located on the first surface 300a on the flexible screen 220 at least partially overlaps with an orthogonal projection of the groove 370 with an opening located on the second surface 300b on the flexible screen 220. A minimum thickness D of the central portion 331 may be a minimum distance between a bottom wall of the groove 370 with the opening located on the first surface 300a and a bottom wall of the groove 370 with the opening located on the second surface 300b.

Exemplarily, the minimum thickness D of the central portion 331 in the first direction X may increase first and then decrease. Thus, the stiffness of the central portion 331 may gradually decrease from the middle to both sides in the first direction X, so that local stress concentration caused by stiffness mutation between the central portion 331 and the main bending portion 332, as well as in the central portion 331 is avoided, thereby alleviating the creases of the support member 300 and avoiding support member 300 from being broken, of which the principle has been explained and will not be repeated.

Exemplarily, in a direction from the central portion 331 to the main bending portion 332, a minimum thickness D of the main bending portion 332 may gradually decrease. Thus, the stiffness of the main bending portion 332 gradually decreases in the direction from the central portion 331 to the main bending portion 332, so that local stress concentration caused by stiffness mutation between the central portion 331 and the main bending portion 332, as well as in the main bending portion 332 is avoided, thereby alleviating the creases of the support member 300 and avoiding support member 300 from being broken, of which the principle has been explained and will not be repeated.

Exemplarily, in a direction from the central portion 331 to the main bending portion 332, a minimum thickness D of the main bending portion 332 may decrease first and then increase. Thus, in the first direction X, the stiffness of the main bending portion 332 may gradually increase from the middle to both sides, so that local stress concentration caused by stiffness mutation between the central portion 331 and the main bending portion 332, between the connecting portion 340 and the main bending portion 332, as well as the main bending portion 332 is avoided, thereby alleviating the creases of the support member 300 and avoiding support member 300 from being broken, of which the principle has been explained and will not be repeated.

In an implementation where the support member 300 is of a multi-layer stacked structure with grooves 370, as shown in FIG. 4 and FIG. 15, a first support layer 351 may be a complete integral layer structure and fully cover the flexible screen 220 of the non-bending area 200b and the bending area 200a, so that the first support layer 351 provides a complete plane. A second support layer 352 may include a plurality of sub-support layers 3521 spaced apart in the first direction X (FIG. 5). An area between two adjacent sub-support layers 3521 is not provided with a sub-support layer 3521, and an opening 354 is formed on the second support layer 352. The opening 354 of the second support layer 352 forms a groove 370 on the support member 300. A stiffness of the support member 300 corresponding to the opening 354 is lower, and stiffnesses of the support member 300 at different positions may be adjusted by adjusting a position of each sub-support layer 3521. For example, the central portion 331, the connecting portion 340, the first bending portion 320, and the fixing portion 310 may all be provided with a sub-support layer 3521, while the main bending portion 332 may not be provided with the sub-support layer 3521. That is, the opening 354 of the second support layer 352 may be located in the main bending portion 332. For example, an orthographic projection of the opening 354 on the first support layer 351 overlaps with a first support layer 351 of the main bending portion 332. At this time, a surface of a side, facing the central portion 331, of the second support layer 352 of the connecting portion 340 and a surface of a side, facing the connecting portion 340, of the second support layer 352 of the central portion 331 form groove sidewalls of the groove 370, and a surface of a side, facing away from the first support layer 351, of a fifth connecting layer 355 of the main bending portion 332 forms a groove bottom wall of the groove 370. Thus, the stiffness of the main bending portion 332 is less than the stiffness of the central portion 331, thereby alleviating the creases of the support member 300, of which the principle has been explained and will not be repeated. By connecting a plurality of sub-support layers 3521 to the first support layer 351 to form the groove 370 on the support member 300, compared to a groove 370 on a support member 300 formed by etching method, the process is simpler, easier to implement, and correspondingly lower in cost.

Therein, a thickness of the second support layer 352 may be higher than a thickness of the first support layer 351. As the thickness of the first support layer 351 is relatively small, overall bending performance of the first support layer 351 is better. As the thickness of the second support layer 352 is relatively large, supporting effect of the second support layer 352 is better. When an opening 354 is provided on the second support layer 352, the support performance and bending performance of the support member 300 is both ensured.

In addition, a thickness of a second support layer 352 of the central portion 331 may be less than a thickness of a second support layer 352 of the fixing portion 310, so that bending performance of the central portion 331 and support performance of the fixing portion 310 is ensured. The connecting portion 340, the first bending portion 320, and the second support layer 352 of the fixing portion 310 may be integrated, thereby reducing preparation difficulty of the connecting portion 340, the first bending portion 320, and the second support layer 300 of the fixing portion 310.

In the following, Example 1 and Example 2 will be explained. In Example 1, a stiffness of a support member 300 in the bending area 200a is less than a stiffness of a support member 300 in the non-bending area 200b, and in the bending area 200a, stiffnesses of the central portion 331, the main bending portion 332, the connecting portion 340, and the first bending portion 320 are all the same. In Example 2, stiffnesses of the main bending portion 332, the central portion 331, the first bending portion 320, and the connecting portion 340 increase sequentially, and the stiffness of the connecting portion 340 is equal to a stiffness of the fixing portion 310. In FIG. 16, S1 shows a curve of a crease depth of Example 1. A crease of a display module 200 in the bending area 200a of Example 1 is in a “V” shape, and the crease depth is about 0.13 mm. In FIG. 16, S2 shows a curve of a crease depth of Example 2. A crease of a display module 200 in the bending area 200a of Example 2 is in a “W” shape, and the crease is more gentle, with a crease depth of about 0.05 mm. Therefore, stiffnesses at different positions of the support member 300 in the bending area 200a are reasonably designed, and the stiffnesses of the central portion 331 and the first bending portion 320 are increased, so that the crease in the display module 200 may be alleviated.

In the following, a description of a display device 100 provided by an embodiment of the present disclosure will be given.

The embodiment provides a display device 100. The display device 100 may include a display module 200. The display device 100 may be a mobile or fixing terminal including the display module 200, such as an electronic paper, a mobile phone, a notebook computer, a television, a monitor, a laptop, a digital photo frame, a super personal computers, a navigation devices.

As shown in FIGS. 17 to 19, the display device 100 may include a housing, and the housing may include a first housing 111 and a second housing 112. The first housing 111 and the second housing 112 are rotatably connected to implement a folding function of the display device 100.

The display device 100 may further include a first supporting member 121 and a second supporting member 122. The first supporting member 121 and the second supporting member 122 are both located on a side, facing away from the flexible screen 220, of the support member 300. The first supporting member 121 may be disposed corresponding to the fixing portion 310, and one fixing portion 310 is connected to one first supporting member 121. The second supporting member 122 may be disposed corresponding to the connecting portion 340, and one connecting portion 340 is connected to one second supporting member 122. Two first supporting members 121 are fixed on the first housing 111 and the second housing 112 respectively, and adjacent first supporting member 121 and second supporting member 122 are rotatably connected. The first supporting member 121 and the second supporting member 122 may provide support for the display module 200. During a folding process of the display device 100, the first supporting member 121 and the second supporting member 122 always provide flat support for the fixing portion 310 and the connecting portion 340, so that the fixing portion 310 and the connecting portion 340 are in a flat state. The two first support members 121 may be rotatably connected through a hinge assembly (not shown in figures), and a shaft cover 113 is provided on a side, facing away from the flexible screen 220, of the hinge assembly, and the shaft cover 113 protects the hinge assembly.

It should be noted that numerical values and numerical ranges involved in the embodiments of the present disclosure are approximate values, and there may be a certain range of error due to an influence of a preparation processes. The error can be considered negligible by those skilled in the art.

Finally, it should be noted that the above embodiments are only used to illustrate the technical solution of the present disclosure, and not to limit it. Although detailed explanations have been provided for the present disclosure with reference to the aforementioned embodiments, a person of ordinary skill in the art should understand that the technical solutions described in the foregoing embodiments may still be modified, or some or all of the technical features thereof may be equivalently replaced; and these modifications or replacements do not make the essence of the corresponding technical solutions deviate from the scope of the technical solutions in the various embodiments of the present disclosure.

What is claimed is:

1. A display module, comprising:
a flexible screen and a support member stacked sequentially, and the support member is located on a backlight side of the flexible screen,
wherein the support member comprises a fixing portion, a first bending portion and a second bending portion arranged in a first direction, the first bending portion is located between the fixing portion and the second bending portion, the second bending portion comprises a central portion and a plurality of main bending portions located on two opposite sides of the central portion in the first direction, and a stiffness of the central portion is higher than a stiffness of the main bending portion.

2. The display module according to claim 1, wherein a stiffness of the first bending portion is higher than the stiffness of the central portion,
a stiffness of the fixing portion is higher than the stiffness of the first bending portion, and
the stiffness of the central portion increases first and then decreases in the first direction.

3. The display module according to claim 1, wherein the stiffness of the main bending portion gradually decreases in a direction from the central portion to the main bending portion; or, the stiffness of the main bending portion decreases first and then increases in the direction from the central portion to the main bending portion.

4. The display module according to claim 1, wherein average stiffnesses of two adjacent unit areas of the second bending portion are a first stiffness and a second stiffness, respectively; an absolute value of a difference between the first stiffness and the second stiffness divided by the first stiffness ranges from 0.05 to 0.2, and
an extension length of the central portion ranges from 1 to 2 mm in the first direction.

5. The display module according to claim 1, wherein the support member further comprises a connecting portion located between the second bending portion and the first bending portion, and a stiffness of the connecting portion is higher than a stiffness of the first bending portion.

6. The display module according to claim 1, wherein a plurality of through holes are provided in the support member at intervals, the through holes penetrate through the support member in a thickness direction of the support member, and a sum of areas of all through holes in a unit area of the central portion is less than a sum of areas of all through holes in a unit area of the main bending portion.

7. The display module according to claim 6, wherein a cross section of the through hole is in a strip shape, the through hole extends in a second direction, and the second direction is perpendicular to the first direction; and
in the second direction, each through hole comprises a first end, a second end, and a middle section located between the first end and the second end, and an extension length of the first end, an extension length of the second end, and an extension length of the middle section in the first direction are all greater than an extension length of a remaining part of the through hole in the first direction.

8. The display module according to claim 7, wherein a through hole group comprises a plurality of through holes arranged at intervals in the second direction, a quantity of the through hole groups is greater than one, a plurality of the through hole groups are arranged at intervals in the first direction, and through holes of two adjacent through hole groups are arranged in a staggered manner in the second direction.

9. The display module according to claim 6, wherein each through hole has a same area, and a distance between two adjacent through holes of the central portion is greater than a distance between two adjacent through holes of the main bending portion.

10. The display module according to claim 9, wherein the distance between two adjacent through holes of the central portion increases first and then decreases in the first direction.

11. The display module according to claim 9, wherein the distance between two adjacent through holes of the main bending portion gradually decreases in a direction from the central portion to the main bending portion; or, the distance between two adjacent through holes of the main bending portion decreases first and then increases in the direction from the central portion to the main bending portion.

12. The display module according to claim 6, wherein a distance between centers of any two adjacent through holes is the same, and an area of the through hole of the central portion is smaller than an area of the through hole of the main bending portion.

13. The display module according to claim 12, wherein the area of the through hole of the central portion decreases first and then increases in the first direction.

14. The display module according to claim 12, wherein the area of the through hole of the main bending portion gradually increases in a direction from the central portion to the main bending portion; or, the area of the through hole of the main bending portion increases first and then decreases in the direction from the central portion to the main bending portion.

15. The display module according to claim 1, wherein the support member is provided with a groove, an opening of the groove is located on at least one of two opposite surfaces in a thickness direction of the support member, and a minimum thickness of the central portion is greater than a minimum thickness of the main bending portion.

16. The display module according to claim 15, wherein the minimum thickness of the central portion increases first and then decreases in the first direction.

17. The display module according to claim 15, wherein a minimum thickness of the main bending portion gradually decreases in a direction from the central portion to the main bending portion; or, the minimum thickness of the main bending portion decreases first and then increases in the direction from the central portion to the main bending portion.

18. The display module according to claim 15, wherein the support member comprises a first support layer, a connecting layer and a second support layer sequentially stacked, the second support layer is provided with an opening, the opening penetrates through the second support layer in a thickness direction of the support member, and the opening is located in the main bending portion.

19. The display module according to claim 18, wherein a thickness of the second support layer is greater than a thickness of the first support layer, and
a thickness of the second support layer of the central portion is less than a thickness of the second support layer of the fixing portion.

20. A display device, comprising a first supporting member, a second supporting member, and a display module according to claim 1, wherein the first supporting member and the second supporting member are located on a side, facing away from a flexible screen of the display module, of a support member of the display module, the first supporting member is disposed corresponding to a fixing portion of the support member, and the second supporting member is disposed corresponding to a connecting portion of the support member.
